(19) United States
(12) Patent Application Publication
(10) Pub. No.: US 2024/0128373 A1
(43) Pub. Date: Apr. 18, 2024

(54) SEMICONDUCTOR DEVICE

(71) Applicant: ROHM CO., LTD., Kyoto-shi (JP)

(72) Inventor: Yusuke SHIMIZU, Kyoto-shi (JP)

(73) Assignee: ROHM CO., LTD., Kyoto-shi (JP)

(21) Appl. No.: 18/398,185

(22) Filed: Dec. 28, 2023

Related U.S. Application Data
(63) Continuation of application No. PCT/JP2022/023165, filed on Jun. 8, 2022.

(30) Foreign Application Priority Data
Jul. 8, 2021 (JP) 2021-113669

(51) Int. Cl. H01L 29/78; H01L 29/49

(52) U.S. Cl. CPC H01L 29/7819; H01L 29/4916

(57) ABSTRACT

The semiconductor device includes a chip which has a main surface, a first conductivity type channel region which is formed in a surface layer portion of the main surface, a second conductivity type drift region which is formed in the surface layer portion of the main surface so as to be adjacent to the channel region, a gate insulating film which covers the channel region and the drift region on the main surface, and a polysilicon gate which has a second conductivity type first portion which faces the channel region across the gate insulating film and a first conductivity type second portion which faces the drift region across the gate insulating film and forms a pn-junction portion with the first portion.

### CROSS-REFERENCE TO RELATED APPLICATIONS

The present application is a bypass continuation of International Patent Application No. PCT/JP2022/023165, filed on Jun. 8, 2022, which claims priority to Japanese Patent Application No. 2021-113669 filed with the Japanese Patent Office on Jul. 8, 2021, the entire disclosure of each is incorporated herein by reference.

### BACKGROUND

### 1. Field of the Disclosure

The present disclosure relates to a semiconductor device.

### 2. Description of the Related Art

Japanese Unexamined Patent Application Publication No. 2015-023208 discloses a field effect transistor that includes a silicon substrate, a drift region, a channel region, a gate insulating film and a polysilicon gate.

### BRIEF DESCRIPTION OF DRAWINGS

FIG. 1 is a plan view which shows a semiconductor device according to a first embodiment.

FIG. 2 is an enlarged view of a region II shown in FIG. 1.

FIG. 3 is a cross-sectional view taken along line III-III shown in FIG. 2.

FIG. 4 is a main portion enlarged view of a structure shown in FIG. 3.

FIG. 5 is a main portion enlarged view which shows a semiconductor device according to a first reference embodiment.

FIG. 6 is a main portion enlarged view which shows a semiconductor device according to a second reference embodiment.

FIG. 7 is a graph which shows a figure of merit.

FIG. 8 is a main portion enlarged view which shows a semiconductor device according to a second embodiment.

FIG. 9 is a main portion enlarged view which shows a semiconductor device according to a third embodiment.

FIG. 10 is a main portion enlarged view which shows a semiconductor device according to a fourth embodiment.

FIG. 11 is a main portion enlarged view which shows a semiconductor device according to a fifth embodiment.

### DETAILED DESCRIPTION OF THE PREFERRED EMBODIMENTS

Hereinafter, a detailed description will be given of the embodiments with reference to accompanying drawings. The accompanying drawings are schematic drawings and not illustrated in a strict manner, and a scale, etc., are not necessarily in agreement. Further, the same reference symbols are given to corresponding structures in the accompanying drawings, with redundant description being omitted or simplified. A description which has been made before omission or simplification will be applied to a structure, the description of which has been omitted or simplified.

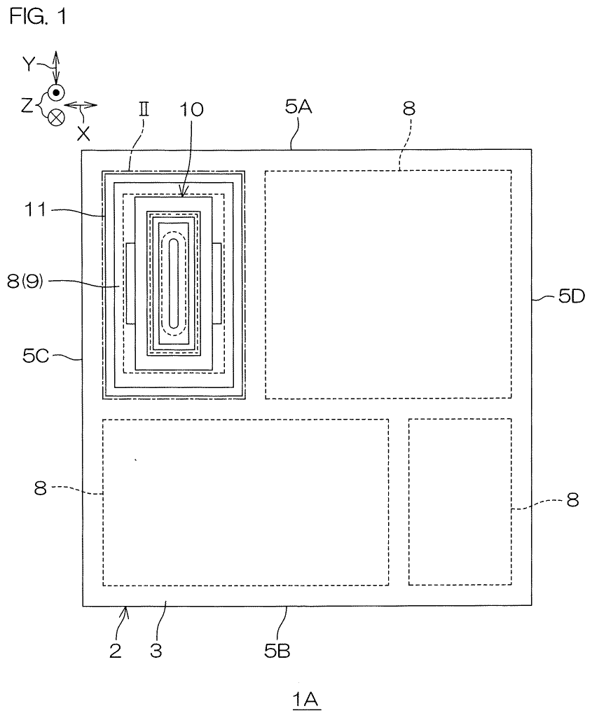

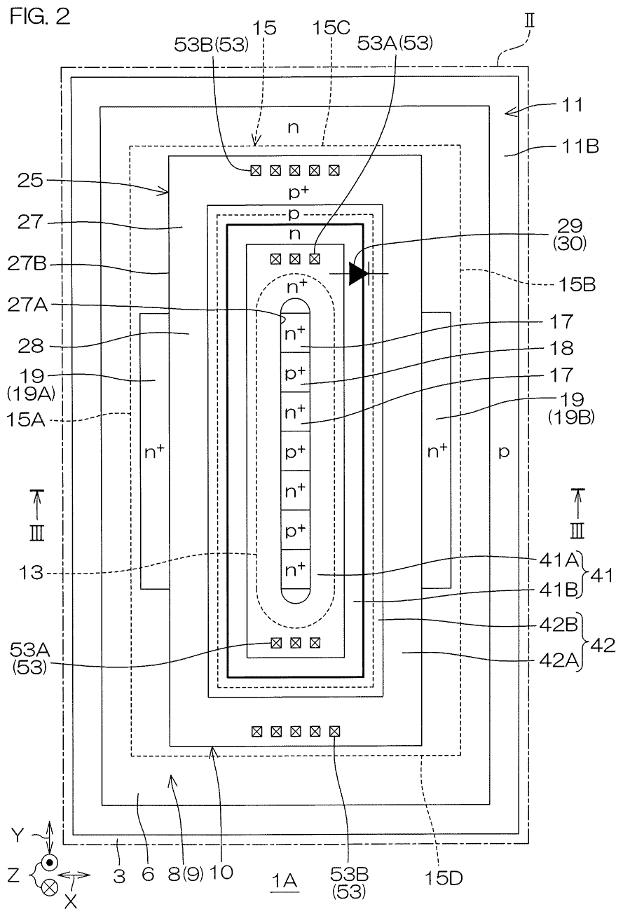

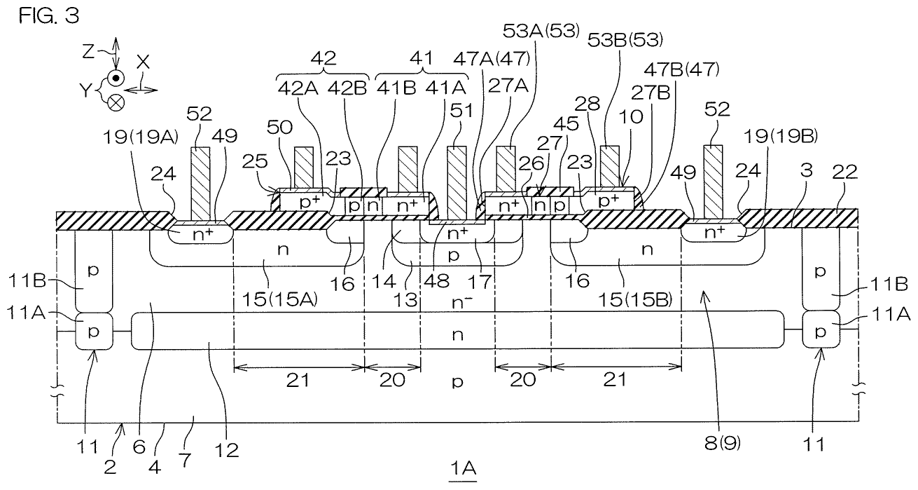

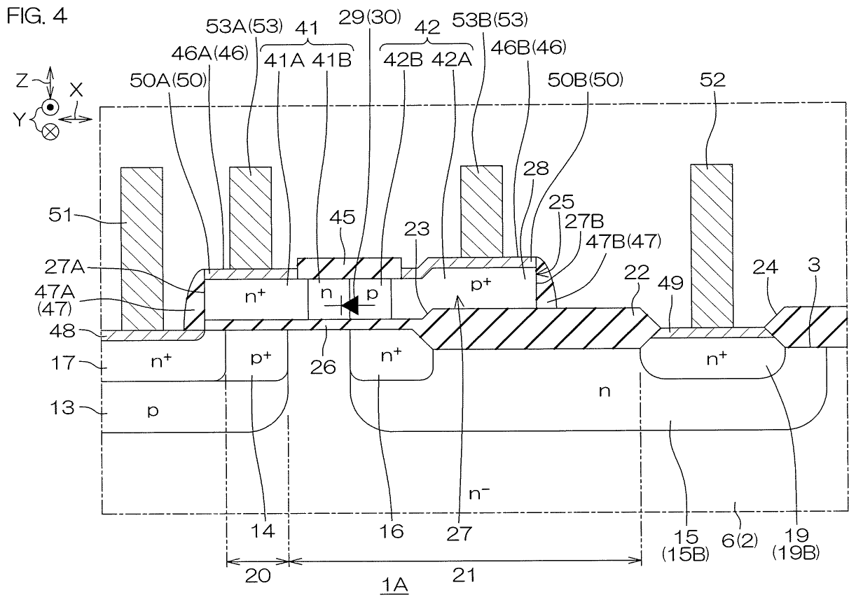

FIG. 1 is a plan view which shows a semiconductor device 1A according to the first embodiment. FIG. 2 is an enlarged view of a region II shown in FIG. 1. FIG. 3 is a cross-sectional view taken along line shown in FIG. 2. FIG. 4 is a main portion enlarged view of a structure shown in FIG. 3. With reference to FIG. 1 to FIG. 4, the semiconductor device 1A includes a chip 2 (semiconductor chip) in a rectangular parallelepiped shape. In this embodiment, the chip 2 is constituted of a silicon chip. The chip 2 has a first main surface 3 on one side, a second main surface 4 on the other side and first to fourth side surfaces 5A to 5D which connect the first main surface 3 and the second main surface 4.

The first main surface 3 and the second main surface 4 are formed in a quadrilateral shape in a plan view as viewed in a normal direction Z thereto. The normal direction Z is also a thickness direction of the chip 2. The first side surface 5A and the second side surface 5B extend along a first direction X along the first main surface 3 and face each other along a second direction Y which intersects in the first direction X (specifically, orthogonal thereto). The third side surface 5C and the fourth side surface 5D extend along the second direction Y and face each other along the first direction X.

The semiconductor device 1A includes an n-type first region 6 which is formed in a surface layer portion of the first main surface 3. The first region 6 is formed as a layer extending along the first main surface 3 and exposed from the first main surface 3 and the first to fourth side surfaces 5A to 5D. That is, the first region 6 has a part of the first main surface 3 and parts of the first to fourth side surfaces 5A to 5D. An n-type impurity concentration of the first region 6 may be not less than 1×10¹⁴ cm⁻³ and not more than 1×10¹⁶ cm⁻³. A thickness of the first region 6 may be not less than 1 μm and not more than 10 μm. In this embodiment, the first region 6 is formed of an n-type epitaxial layer.

The semiconductor device 1A includes a p-type second region 7 which is formed in a surface layer portion of the second main surface 4. The second region 7 may be referred to as a “base region.” The second region 7 is formed as a layer extending along the second main surface 4 and exposed from the second main surface 4 and the first to fourth side surfaces 5A to 5D. That is, the second region 7 has a part of the second main surface 4 and parts of the first to fourth side surfaces 5A to 5D. The second region 7 is connected to the first region 6 inside the chip 2.

The second region 7 may have a p-type impurity concentration which is substantially fixed in a thickness direction. A p-type impurity concentration of the second region 7 may be not less than 1×10¹⁴ cm⁻³ and not more than 1×10¹⁸ cm⁻³. A thickness of the second region 7 may be not less than 100 μm and not more than 1000 μm. The thickness of the second region 7 is adjusted by grinding the second main surface 4. In this embodiment, the second region 7 is formed of a p-type semiconductor substrate. That is, the chip 2 has a laminated structure including a semiconductor substrate and an epitaxial layer. The second region 7 is formed in the semiconductor substrate, and the first region 6 is formed in the epitaxial layer.

The semiconductor device 1A includes a plurality of device regions 8 which are arranged in the first region 6. The plurality of device regions 8 are respectively demarcated at internal portions of the first main surface 3 at an interval from the first to fourth side surfaces 5A to 5D in a plan view. The number of the device regions 8, an arrangement and a shape thereof are arbitrary, and there is no restriction on the number, the arrangement and the shape. The plurality of device regions 8 each include various functional devices. The functional device may include at least one of a semiconductor switching device, a semiconductor rectifying device and a passive device.

The semiconductor switching device may include at least one of a BJT (Bipolar Junction Transistor), a JFET (Junction Field Effect Transistor), a MISFET (Metal Insulator Semiconductor Field Effect Transistor) and an IGBT (Insulated Gate Bipolar Junction Transistor). The semiconductor rectifying device may include at least one of a pn-junction diode 29, a pin junction diode, a Zener diode, a Schottky barrier diode and a fast recovery diode. The passive device may include at least one of a resistor, a capacitor, an inductor and a fuse.

In this embodiment, the plurality of device regions 8 include at least one MIS region 9 (refer to region II in FIG. 1). The MIS region 9 is a region which includes at least one transistor cell 10. Hereinafter, a description will be given of a specific structure on the MIS region 9 side.

With reference to FIG. 2 and FIG. 3, the semiconductor device 1A includes a p-type separation region 11 as one example of a region separation structure which demarcates the MIS region 9 in the first main surface 3. The separation region 11 is formed in an annular shape which surrounds a part of the first main surface 3 in a plan view and demarcates the MIS region 9 having a predetermined shape. The separation region 11 electrically separates the MIS region 9 from the other region (device region 8).

In this embodiment, the separation region 11 is formed in a quadrilateral annular shape (specifically, in a rectangular annular shape extending in the second direction Y) in a plan view and demarcates the MIS region 9 in a quadrilateral shape (specifically, a rectangular shape extending in the second direction Y) by an inner edge. A planar shape of the separation region 11 (planar shape of MIS region 9) is arbitrary. The separation region 11 extends as a wall from the first main surface 3 to the second region 7 so as to cross the first region 6 and is electrically connected to the second region 7.

In this embodiment, the separation region 11 has a laminated structure which includes a first layer 11A and a second layer 11B. The first layer 11A is formed in a boundary portion between the first region 6 and the second region 7. The first layer 11A is formed at an interval from the first main surface 3 and the second main surface 4 with regard to the normal direction Z and electrically connected to the first region 6 and the second region 7. The first layer 11A has a p-type impurity concentration which is higher than that of the second region 7.

The second layer 11B is formed in a region between the first main surface 3 and the first layer 11A in the first region 6 and electrically connected to the first layer 11A. The second layer 11B may have a p-type impurity concentration which is not more than the p-type impurity concentration of the first layer 11A. In this embodiment, although one second layer 11B is formed, the number of the second layers 11B (the laminated number of them) is arbitrary as long as they are electrically connected to the first layer 11A.

Therefore, the plurality of second layers 11B may be laminated in a region between the first main surface 3 and the first layer 11A. As a matter of course, the separation region 11 is not necessarily required to have a laminated structure which includes the first layer 11A and the second layer 11B but may have a single layer structure which is constituted of the single second layer 11B, as long as the MIS region 9 can be demarcated.

The semiconductor device 1A includes an n-type embedded region 12 which is formed inside the chip 2 so as to cross a bottom portion of the first region 6 in the MIS region 9. Specifically, the embedded region 12 is formed in a boundary portion between the first region 6 and the second region 7. The embedded region 12 has an n-type impurity concentration which is higher than that of the first region 6. The n-type impurity concentration of the embedded region 12 may be not less than 1×10¹⁷ cm⁻³ and not more than 1×10¹⁹ cm⁻³.

The embedded region 12 is formed at an interval from the first main surface 3 and the second main surface 4 with regard to the normal direction Z and electrically connected to the first region 6 and the second region 7. The embedded region 12 is formed inside the MIS region 9 at an interval from an inner edge of the separation region 11 and exposes a part of the second region 7 at a peripheral edge portion of the MIS region 9. In this embodiment, the embedded region 12 is formed in a quadrilateral shape (specifically, in a rectangular shape extending in the second direction Y) along the inner edge of the separation region 11 in a plan view.

The semiconductor device 1A includes a p-type body region 13 which is formed in a surface layer portion of the first region 6 in the MIS region 9. The body region 13 has a p-type impurity concentration higher than the n-type impurity concentration of the first region 6. The p-type impurity concentration of the body region 13 may be not less than 1×10¹⁶ cm⁻³ and not more than 1×10¹⁸ cm⁻³.

The body region 13 is internally formed at an interval from the separation region 11 in a plan view. Specifically, the body region 13 is formed inside a region which is surrounded by a peripheral edge of the embedded region 12 internally at an interval from the peripheral edge of the embedded region 12 in a plan view. That is, an entire area of the body region 13 faces the embedded region 12 in a plan view.

In this embodiment, the body region 13 is formed as a band extending in the second direction Y in a plan view. The body region 13 has both end portions which are curved in a circular arc shape toward the outside with regard to the second direction Y. The body region 13 is formed at an interval from the bottom portion of the first region 6 (specifically, embedded region 12) to the first main surface 3 side with regard to the normal direction Z.

In this embodiment, the semiconductor device 1A includes a p-type high concentration body region 14 which is formed in a surface layer portion of the body region 13. The high concentration body region 14 has a p-type impurity concentration higher than that of the body region 13. The high concentration body region 14 is a region in which the p-type impurity concentration is raised at the surface layer portion of the body region 13 and forms a part of the body region 13.

The p-type impurity concentration of the high concentration body region 14 may be not less than 1×10¹⁶ cm⁻³ and not more than 1×10¹⁸ cm⁻³. The high concentration body region 14 faces the first region 6 across a part of the body region 13 which is formed in the surface layer portion of the body region 13 at an interval from a bottom portion of the body region 13 to the first main surface 3 side.

The semiconductor device 1A includes at least one (one in this embodiment) n-type well region 15 which is formed in a surface layer portion of the first region 6 at an interval from the body region 13 in the MIS region 9. The well region 15 has an n-type impurity concentration which is higher than that of the first region 6. The n-type impurity concentration of the well region 15 may be not less than 1×10¹⁵ cm⁻³ and not more than 1×10¹⁷ cm⁻³.

The well region 15 is internally formed at an interval from the separation region 11 in a plan view. Specifically, the well region 15 is formed inside a region which is surrounded by the peripheral edge of the embedded region 12 at an interval from the peripheral edge of the embedded region 12 in a plan view. That is, an entire area of the well region 15 faces the embedded region 12 in a plan view. In this embodiment, the well region 15 is formed in an annular shape which surrounds the body region 13 in a plan view.

An inner edge of the well region 15 may be formed in an elliptical shape or a quadrilateral shape (specifically, a rectangular shape) in a plan view. An outer edge of the well region 15 may be formed in an elliptical shape or a quadrilateral shape (specifically, a rectangular shape) in a plan view. A planar shape of the outer edge of the well region 15 is not necessarily required to be in agreement with a planar shape of the inner edge of the well region 15.

The well region 15 integrally includes first to fourth well portions 15A to 15D. The first well portion 15A is arranged on one side (third side surface 5C side) in the first direction X at an interval from the body region 13 and formed as a band extending in the second direction Y in a plan view. The second well portion 15B is arranged on the other side (fourth side surface 5D side) in the first direction X at an interval from the body region 13 and formed as a band extending in the second direction Y in a plan view. The second well portion 15B faces the first well portion 15A across the body region 13.

The third well portion 15C is arranged on one side (first side surface 5A side) in the second direction Y at an interval from the body region 13 and formed as a band extending in the first direction X in a plan view. The third well portion 15C is connected to one end portions of the first to second well portions 15A to 15B.

The fourth well portion 15D is arranged on the other side (second side surface 5B side) in the second direction Y at an interval from the body region 13 and formed as a band extending in the first direction X in a plan view. The fourth well portion 15D faces the third well portion 15C across the body region 13. The fourth well portion 15D is connected to the other end portions of the first to second well portions 15A to 15B.

In this embodiment, the semiconductor device 1A includes an n-type high concentration well region 16 which is selectively formed in a surface layer portion of the well region 15. The high concentration well region 16 has an n-type impurity concentration higher than that of the well region 15. The high concentration well region 16 is a region in which the n-type impurity concentration is raised at the surface layer portion of the well region 15 and forms a part of the well region 15.

The n-type impurity concentration of the high concentration well region 16 may be not less than 1×10¹⁵ cm⁻³ and not more than 1×10¹⁷ cm⁻³. The high concentration well region 16 is formed in the surface layer portion of the well region 15 on the first main surface 3 side at an interval from a bottom portion of the well region 15 and faces the first region 6 across a part of the well region 15.

In this embodiment, the high concentration well region 16 is introduced into the surface layer portion of the well region 15 on the inner edge side (a peripheral edge on the body region 13 side) but not introduced into the surface layer portion of the well region 15 on the outer edge side (a peripheral edge on the separation region 11 side). As a matter of course, the high concentration well region 16 may be introduced into the surface layer portion of the well region 15 on the outer edge side (a peripheral edge on the separation region 11 side). Further, the high concentration well region 16 may be introduced into an entire area of the surface layer portion of the well region 15.

The semiconductor device 1A includes at least one n-type source region 17 (in this embodiment, a plurality of them) formed in the surface layer portion of the body region 13 in the MIS region 9. The source region 17 has an n-type impurity concentration higher than that of the first region 6. In this embodiment, the n-type impurity concentration of each of the source regions 17 is higher than that of the well region 15. The n-type impurity concentration of each of the source regions 17 is preferably higher than that of the high concentration well region 16. The n-type impurity concentration of each of the source regions 17 may be not less than 1×10¹⁹ cm⁻³ and not more than 1×10²¹ cm⁻³.

The plurality of source regions 17 are each internally formed at an interval from a peripheral edge of the body region 13 in a plan view and arrayed at an interval in the second direction Y. The plurality of source regions 17 are arbitrary in terms of a planar shape and may be formed in a quadrilateral shape, a hexagonal shape or a circular shape. The plurality of source regions 17 are formed on the first main surface 3 side at an interval from the bottom portion of the body region 13 with regard to the normal direction Z and face the second region 7 across a part of the body region 13.

The plurality of source regions 17 may be formed deeper than the high concentration body region 14 or may be formed shallower than the high concentration body region 14. The plurality of source regions 17 are electrically connected to the high concentration body region 14 with regard to the first direction X and face the second region 7 across a part of or an entirety of the high concentration body region 14.

The semiconductor device 1A includes at least one p-type contact region 18 (in this embodiment, a plurality of them) formed in the surface layer portion of the body region 13 in the MIS region 9. Each of the contact regions 18 has a p-type impurity concentration higher than that of the body region 13. The p-type impurity concentration of each of the contact regions 18 is higher than that of the high concentration body region 14. The p-type impurity concentration of each of the contact regions 18 may be not less than 1×10¹⁹ cm⁻³ and not more than 1×10²¹ cm⁻³.

The plurality of contact regions 18 are each internally formed at an interval from the peripheral edge of the body region 13 so as to be connected to the plurality of source regions 17 in a plan view and arrayed at an interval in the second direction Y. Specifically, the plurality of contact regions 18 are arrayed alternately with the plurality of source regions 17 along the second direction Y so as to hold one source region 17 between them. The plurality of contact regions 18 are arbitrary in terms of a planar shape and may be formed in a quadrilateral shape, a hexagonal shape or a circular shape.

The plurality of contact regions 18 are formed on the first main surface 3 side at an interval from the bottom portion of the body region 13 with regard to the normal direction Z and face the second region 7 across a part of the body region 13. The plurality of contact regions 18 may be formed deeper than the high concentration body region 14 or may be formed shallower than the high concentration body region 14. The plurality of contact regions 18 are electrically connected to the high concentration body region 14 with regard to the first direction X and face the second region 7 across a part of or an entirety of the high concentration body region 14.

The semiconductor device 1A includes at least one n-type drain region 19 (in this embodiment, two of them) formed in a surface layer portion of the well region 15 in the MIS region 9. Each of the drain regions 19 has an n-type impurity concentration higher than that of the well region 15. The n-type impurity concentration of each of the drain regions 19 is preferably higher than that of the high concentration well region 16. The n-type impurity concentration of each of the drain regions 19 may be not less than 1×10¹⁹ cm⁻³ and not more than 1×10²¹ cm⁻³. The n-type impurity concentration of each of the drain regions 19 is preferably substantially equal to an n-type impurity concentration of the source region 17.

The plurality of drain regions 19 are internally formed at an interval from a peripheral edge of the well region 15 in a plan view. Specifically, the plurality of drain regions 19 are formed in the surface layer portion of the well region 15 on the outer edge side of the well region 15 at an interval from the high concentration well region 16. The plurality of drain regions 19 are formed on the first main surface 3 side at an interval from the bottom portion of the body region 13 with regard to a thickness direction and face the first region 6 across a part of the well region 15.

In this embodiment, the plurality of drain regions 19 include a first drain region 19A and a second drain region 19B. The first drain region 19A is arranged at a surface layer portion of the first well portion 15A and formed as a band extending in the second direction Y in a plan view. The second drain region 19B is arranged at a surface layer portion of the second well portion 15B and formed as a band extending in the second direction Y in a plan view. In this embodiment, the drain region 19 is not formed in the third or the fourth well portion 15C or 15D.

The semiconductor device 1A includes a p-type channel region 20 which is formed in the surface layer portion of the first main surface 3 in the MIS region 9. The channel region 20 is a region in which conduction or non-conduction of a drain/source current is controlled. The channel region 20 is formed in a region on the source region 17 side between the source region 17 and the drain region 19. Specifically, the channel region 20 is formed in a region between the first region 6 and the plurality of source regions 17 at the surface layer portion of the body region 13 (high concentration body region 14).

The semiconductor device 1A includes an n-type drift region 21 which is formed in the surface layer portion of the first main surface 3 so as to be adjacent to the channel region 20 in the MIS region 9. The drift region 21 is a region which serves as a current path of the drain/source current. The drift region 21 is formed in a region on the drain region 19 side between the source region 17 and the drain region 19. Specifically, the drift region 21 is formed in the first region 6 and also in the well region 15 in a region between the body region 13 (high concentration body region 14) and the drain region 19.

The semiconductor device 1A includes a field insulating film 22 which selectively covers the drift region 21 on the first main surface 3. The field insulating film 22 preferably includes a silicon oxide film. Specifically, the field insulating film 22 includes a first opening 23 which selectively covers an interior and an exterior of the well region 15 in a plan view and exposes the plurality of source regions 17 and a plurality of second openings 24 which expose the plurality of drain regions 19.

Specifically, the first opening 23 has a wall portion which is positioned on the inner edge of the well region 15 (high concentration well region 16) and exposes the inner edge of the well region 15 (high concentration well region 16), the first region 6, the body region 13 (high concentration body region 14), the plurality of source regions 17 and the plurality of contact regions 18. Specifically, the plurality of second openings 24 each have a wall portion which is positioned on a peripheral edge portion of a corresponding drain region 19 and expose each of the drain regions 19 which correspond in a one-to-one correspondence.

The semiconductor device 1A includes a planar gate structure 25 which is formed on the first main surface 3 so as to cover the channel region 20 and the drift region 21 in the MIS region 9. The planar gate structure 25 is constituted so as to control inversion and non-inversion of the channel region 20.

Specifically, the planar gate structure 25 has a laminated structure which includes a gate insulating film 26 and a poly-gate 27. The gate insulating film 26 preferably includes a silicon oxide film. The poly-gate 27 is a gate electrode which contains conductive polysilicon. The poly-gate 27 may be referred to as a “polysilicon gate.”

The gate insulating film 26 has a thickness which is less than a thickness of the field insulating film 22. The gate insulating film 26 covers the channel region 20 and the drift region 21 inside the first opening 23 of the field insulating film 22 and continues to the field insulating film 22. Specifically, the gate insulating film 26 covers the inner edge of the well region 15 (high concentration well region 16), the first region 6, the body region 13 (high concentration body region 14), the plurality of source regions 17 and the plurality of contact regions 18. In this embodiment, the gate insulating film 26 is formed in an annular shape which surrounds an internal portion of the body region 13 in a plan view.

The poly-gate 27 is formed on the gate insulating film 26 and faces the channel region 20 and the drift region 21 across the gate insulating film 26. Specifically, the poly-gate 27 faces the inner edge of the well region 15 (high concentration well region 16), the first region 6, the body region 13 (high concentration body region 14), the plurality of source regions 17 and the plurality of contact regions 18 across the gate insulating film 26. In this embodiment, the poly-gate 27 is formed in an annular shape which surrounds the internal portion of the body region 13 in a plan view.

The poly-gate 27 has an inner wall 27A on the body region 13 side and an outer wall 27B on the well region 15 side. The inner wall 27A is arranged on the body region 13. The inner wall 27A may be formed in an elliptical shape or a rectangular shape extending along the peripheral edge of the body region 13. The inner wall 27A demarcates an opening which exposes the plurality of source regions 17 and the plurality of contact regions 18 on the internal portion side of the body region 13.

The outer wall 27B is arranged on the well region 15. In this embodiment, the outer wall 27B is arranged in a region between the inner edge of the well region 15 and the plurality of drain regions 19 in a plan view. The outer wall 27B is preferably arranged in a region between the high concentration well region 16 and the plurality of drain regions 19. The outer wall 27B may be formed in an elliptical shape or a rectangular shape extending along an outer edge (inner edge) of the well region 15. A planar shape of the outer wall 27B is not necessarily required to be in agreement with a planar shape of the inner wall 27A.

In this embodiment, the poly-gate 27 includes a lead-out portion 28 which is led out on the field insulating film 22 from on the gate insulating film 26. The lead-out portion 28 forms the outer wall 27B. That is, the outer wall 27B of the poly-gate 27 is arranged on the field insulating film 22. The lead-out portion 28 is formed on the inner edge side of the well region 15 at an interval from the side of the plurality of drain regions 19 in a plan view and faces the drift region 21 (well region 15) across the field insulating film 22. The lead-out portion 28 does not face the plurality of drain regions 19.

The semiconductor device 1A includes a pn-junction diode 29 which is formed inside the poly-gate 27 (polysilicon of gate electrode). The pn-junction diode 29 may be regarded as a constituent of the poly-gate 27. The pn-junction diode 29 has a pn-junction portion 30 (barrier) between the inner wall 27A and the outer wall 27B of the poly-gate 27 and is constituted so as to restrict a carrier which moves from the inner wall 27A (source region 17) side to the outer wall 27B (drain region 19) side.

Specifically, the pn-junction diode 29 is constituted so as to restrict a carrier that moves from a portion of the poly-gate 27 which is positioned on the channel region 20 to a portion of the poly-gate 27 which is positioned on the drift region 21. In other words, the pn-junction diode 29 electrically separates the portion which is positioned on the channel region 20 from the portion which is positioned on the drift region 21 with regard to the poly-gate 27.

The pn-junction diode 29 is constituted so that a potential difference between the inner wall 27A and the outer wall 27B will be less than a forward threshold voltage Vdth of the pn-junction portion 30 inside the poly-gate 27. Specifically, the pn-junction diode 29 includes a p-type first polarity portion 41 (first portion) and an n-type second polarity portion 42 (second portion) which are formed inside the poly-gate 27.

The first polarity portion 41 and the second polarity portion 42 may be both regarded as a constituent of the poly-gate 27. The first polarity portion 41 faces the channel region 20 across the gate insulating film 26. The second polarity portion 42 faces the drift region 21 across the gate insulating film 26 and forms the pn-junction portion 30 with the first polarity portion 41 inside the poly-gate 27.

That is, the pn-junction diode 29 has the n-type first polarity portion 41 which is opposite in polarity to the channel region 20 on the p-type channel region 20 and has the p-type second polarity portion 42 which is opposite in polarity to the drift region 21 on the n-type drift region 21. A first potential V1 (here, cathode potential) is to be imparted to the first polarity portion 41, and a second potential V2 (here, anode potential) which is different from the first potential V1 is to be imparted to the second polarity portion 42.

In this embodiment, a gate potential Vg (V1=Vg) as the first potential V1 is to be imparted to the first polarity portion 41. On the other hand, a potential (V2≠Vg) other than the gate potential Vg is to be imparted to the second polarity portion 42. That is, the first polarity portion 41 functions as a main gate electrode which controls the channel region 20 inside the poly-gate 27.

A predetermined potential difference V12 is to be imparted between the first polarity portion 41 and the second polarity portion 42. The predetermined potential difference V12 is set at a value less than a forward threshold voltage Vdth of the pn-junction diode 29 (V12<Vdth). A floating potential, a reference potential or a ground potential is given as an example of the second potential V2.

The floating potential is a potential which naturally occurs at the second polarity portion 42 in an electrically opened state. That is, a state in which the floating potential is applied to the second polarity portion 42 means that the second polarity portion 42 is formed in an electrically floating state. The reference potential is a potential which serves as a reference of circuit operation. The reference potential may be a ground potential or a potential other than the ground potential.

In the pn-junction diode 29, the above-described structure restricts a carrier which moves from the first polarity portion 41 to the second polarity portion 42. An increase in the facing area of the n-type first polarity portion 41 in relation to the p-type channel region 20 will result in a decrease in gate threshold voltage Vgth of the poly-gate 27.

On the other hand, an increase in the facing area of the p-type second polarity portion 42 in relation to the p-type channel region 20 will result in a change in work function inside the poly-gate 27 and an increase in gate threshold voltage Vgth. Therefore, the gate threshold voltage Vgth can be adjusted by adjusting a layout of the first polarity portion 41 and that of the second polarity portion 42. In general, the gate threshold voltage Vgth is preferably low.

In this embodiment, the first polarity portion 41 is led out on the drift region 21 from on the channel region 20 and faces the channel region 20 and the drift region 21 across the gate insulating film 26. The first polarity portion 41 is formed only on the gate insulating film 26. In this embodiment, the first polarity portion 41 is formed in an annular shape extending along the inner wall 27A of the poly-gate 27 in a plan view.

The first polarity portion 41 is exposed from the inner wall 27A of the poly-gate 27. An outer edge of the first polarity portion 41 may be formed in an elliptical shape or a quadrilateral shape (specifically, a rectangular shape) in a plan view. A planar shape of the outer edge of the first polarity portion 41 is not necessarily required to be in agreement with a planar shape of an inner edge of the first polarity portion 41.

On the other hand, in this embodiment, the second polarity portion 42 is formed in a region outside the channel region 20 in a plan view and faces the drift region 21 across the gate insulating film 26. Further, the second polarity portion 42 is led out on the field insulating film 22 from on the gate insulating film 26 and faces the drift region 21 across the gate insulating film 26 and the field insulating film 22. The second polarity portion 42 does not face the channel region 20 across the gate insulating film 26.

In this embodiment, the second polarity portion 42 is formed in an annular shape extending along the first polarity portion 41 in a plan view. The second polarity portion 42 is exposed from the outer wall 27B of the poly-gate 27. An inner edge of the second polarity portion 42 may be regulated according to a planar shape of the outer edge of the first polarity portion 41 and formed in an elliptical shape or a quadrilateral shape (specifically, a rectangular shape) in a plan view. A planar shape of an outer edge of the second polarity portion 42 is not necessarily required to be in agreement with a planar shape of the inner edge of the second polarity portion 42.

The second polarity portion 42 forms the pn-junction portion 30 which extends in an annular shape in a plan view with the first polarity portion 41. In this embodiment, the pn-junction portion 30 is formed in a region outside the body region 13 in a plan view and surrounds the body region 13. The pn-junction portion 30 is preferably positioned in a region between the peripheral edge of the body region 13 and an outer edge portion of the gate insulating film 26 (inner wall portion of the field insulating film 22) in a plan view.

In this embodiment, the pn-junction portion 30 faces the drift region 21 across the body region 13 but does not face the channel region 20. The pn-junction portion 30 may face the first region 6 across the gate insulating film 26 or may face the well region 15 (high concentration well region 16) across the gate insulating film 26.

As a matter of course, the pn-junction portion may be arranged on the field insulating film 22. However, in this case, the first polarity portion 41 is increased in volume, and a charge speed of a carrier (response speed of the transistor) to the first polarity portion 41 is lowered. Therefore, the pn-junction portion 30 is preferably positioned on the gate insulating film 26.

In this embodiment, the first polarity portion 41 has a concentration gradient which is decreased in n-type impurity concentration from the inner wall 27A side to the outer wall 27B side of the poly-gate 27. Specifically, the first polarity portion 41 includes an n-type first high concentration portion 41A and an n-type first low concentration portion 41B. The first high concentration portion 41A has a relatively high n-type impurity concentration and is formed on the inner wall 27A side of the poly-gate 27.

The first high concentration portion 41A is formed in an annular shape extending along the inner wall 27A of the poly-gate 27 in a plan view. An outer edge of the first high concentration portion 41A may be formed in an elliptical shape or a quadrilateral shape (specifically, a rectangular shape) in a plan view. The first high concentration portion 41A is preferably led out on the drift region 21 from on the channel region 20 and faces the channel region 20 and the drift region 21 across the gate insulating film 26. The first high concentration portion 41A preferably faces the first region 6 and the body region 13 (high concentration body region 14) across the gate insulating film 26.

The first low concentration portion 41B has an n-type impurity concentration lower than that of the first high concentration portion 41A and is formed on the outer wall 27B side of the poly-gate 27 in relation to the first high concentration portion 41A. The first low concentration portion 41B is formed in an annular shape extending along the first high concentration portion 41A in a plan view. An outer edge of the first low concentration portion 41B may be formed in an elliptical shape or a quadrilateral shape (specifically, a rectangular shape) in a plan view. A planar shape of the outer edge of the first low concentration portion 41B is not necessarily required to be in agreement with a planar shape of the inner edge of the second polarity portion 42.

The first low concentration portion 41B is preferably positioned on the gate insulating film 26 and faces the drift region 21 across the gate insulating film 26. The first low concentration portion 41B is preferably positioned in a region between the peripheral edge of the body region 13 and the outer edge portion of the gate insulating film 26 (inner wall portion of field insulating film 22) in a plan view. The first low concentration portion 41B preferably faces at least one of the first region 6 and the well region 15 (high concentration well region 16) across the gate insulating film 26.

The first low concentration portion 41B preferably has a width which is not more than a width of the first high concentration portion 41A (preferably, less than a width of the first high concentration portion 41A) in a plan view. The width of the first high concentration portion 41A and the width of the first low concentration portion 41B are a width in a direction orthogonal to a direction in which they extend in a plan view. A planar area (volume) of the first low concentration portion 41B which occupies inside the poly-gate 27 (first polarity portion 41) is preferably less than a planar area (volume) of the first high concentration portion 41A which occupies inside the poly-gate 27 (first polarity portion 41).

The n-type impurity concentration of the first high concentration portion 41A may be not less than 1×10¹² cm⁻³ and not more than 1×10²¹ cm⁻³. The n-type impurity concentration of the first low concentration portion 41B may be not less than 1×10¹⁶ cm⁻³ and not more than 1×10¹⁸ cm⁻³. The first polarity portion 41 (first high concentration portion 41A) may contain an n-type impurity (pentavalent element) which is the same type as an n-type impurity (pentavalent element) of the source region 17. Further, the first polarity portion 41 (first high concentration portion 41A) may have an n-type impurity concentration which is substantially equal to the n-type impurity concentration of the source region 17. According to this structure, the first polarity portion 41 can be formed by utilizing steps of forming the source region 17.

In this embodiment, the second polarity portion 42 has a concentration gradient which is decreased in p-type impurity concentration from the outer wall 27B side to the inner wall 27A side of the poly-gate 27. Specifically, the second polarity portion 42 includes a p-type second high concentration portion 42A and a p-type second low concentration portion 42B. The second high concentration portion 42A has a relatively high p-type impurity concentration and is formed on the outer wall 27B side of the poly-gate 27. The second high concentration portion 42A is formed in an annular shape extending along the outer wall 27B of the poly-gate 27 in a plan view. An inner edge of the second high concentration portion 42A may be formed in an elliptical shape or a quadrilateral shape (specifically, a rectangular shape) in a plan view.

The second high concentration portion 42A is preferably led out on the field insulating film 22 from on the gate insulating film 26 and faces the drift region 21 across the gate insulating film 26 and the field insulating film 22. The second high concentration portion 42A preferably faces the high concentration well region 16 across the gate insulating film 26 and faces the well region across the field insulating film 22.

The second low concentration portion 42B has a p-type impurity concentration lower than that of the second high concentration portion 42A and is formed on the inner wall 27A side of the poly-gate 27 in relation to the second high concentration portion 42A. The second low concentration portion 42B is interposed between the first low concentration portion 41B and the second high concentration portion 42A and formed in an annular shape extending along the first low concentration portion 41B in a plan view.

An inner edge of the second low concentration portion 42B may be adjusted according to a planar shape of the inner edge of the first low concentration portion 41B and formed in an elliptical shape or a quadrilateral shape (specifically, a rectangular shape) in a plan view. A planar shape of the inner edge of the second low concentration portion 42B is not necessarily required to be in agreement with a planar shape of the inner edge of the second high concentration portion 42A.

The second low concentration portion 42B forms the pn-junction portion 30 with the first low concentration portion 41B. The second low concentration portion 42B is preferably positioned on the gate insulating film 26 and faces the drift region 21 across the gate insulating film 26. The second low concentration portion 42B preferably faces at least one of the first region 6 and the well region 15 (high concentration well region 16) across the gate insulating film 26.

The second low concentration portion 42B preferably has a width which is not more than a width of the second high concentration portion 42A (preferably less than a width of the second high concentration portion 42A) in a plan view. The width of the second high concentration portion 42A and the width of the second low concentration portion 42B are widths in a direction orthogonal to a direction in which they extend in a plan view. A planar area (volume) of the second low concentration portion 42B which occupies inside the poly-gate 27 (second polarity portion 42) is preferably less than a planar area (volume) of the second high concentration portion 42A which occupies inside the poly-gate 27 (second polarity portion 42).

An n-type impurity concentration of the second high concentration portion 42A may be not less than 1×10¹² cm⁻³ and not more than 1×10²¹ cm⁻³. An n-type impurity concentration of the second low concentration portion 42B may be not less than 1×10¹⁶ cm⁻³ and not more than 1×10¹⁸ cm⁻³. The second polarity portion 42 (second high concentration portion 42A) may contain a p-type impurity (trivalent element) that is the same type as a p-type impurity (trivalent element) of the contact region 18. Further, the second polarity portion 42 (second high concentration portion 42A) may have a p-type impurity concentration which is substantially equal to the p-type impurity concentration of the contact region 18. According to this structure, the second polarity portion 42 can be formed by utilizing steps of forming the contact region 18.

The semiconductor device 1A includes a cap insulating film 45 which selectively covers a main surface of the poly-gate 27. The cap insulating film 45 preferably contains silicon oxide. The cap insulating film 45 selectively covers the main surface of the poly-gate 27 so as to cover the pn-junction portion 30. That is, the cap insulating film 45 covers the first polarity portion 41 and the second polarity portion 42. The cap insulating film 45 has a removing portion 46 which exposes a portion other than the pn-junction portion 30 in the main surface of the poly-gate 27.

In this embodiment, the removing portion 46 includes a first removing portion 46A and a second removing portion 46B. The first removing portion 46A exposes the first polarity portion 41. The first removing portion 46A preferably exposes at least the first high concentration portion 41A. The first removing portion 46A may expose both of the first high concentration portion 41A and the first low concentration portion 41B. The first removing portion 46A may be formed in an annular shape extending along the first polarity portion 41 in a plan view. As a matter of course, the plurality of first removing portions 46A may be formed at an interval along the first polarity portion 41.

The second removing portion 46B exposes the second polarity portion 42. The second removing portion 46B preferably exposes at least the second high concentration portion 42A. The second removing portion 46B may expose both of the second high concentration portion 42A and the second low concentration portion 42B. The second removing portion 46B may be formed in an annular shape extending along the second polarity portion 42 in a plan view. As a matter of course, the plurality of second removing portions 46B may be formed at an interval along the second polarity portion 42.

The semiconductor device 1A includes a side wall insulating film 47 which covers a side wall of the poly-gate 27. The side wall insulating film 47 preferably includes one of or both of a silicon oxide and a silicon nitride film. The side wall insulating film 47 includes a first side wall insulating film 47A and a second side wall insulating film 47B. The first side wall insulating film 47A covers the inner wall 27A of the poly-gate 27.

Specifically, the first side wall insulating film 47A covers the first polarity portion 41 (first high concentration portion 41A) which is exposed from the inner wall 27A. The second side wall insulating film 47B covers the outer wall 27B of the poly-gate 27. Specifically, the second side wall insulating film 47B covers the second polarity portion 42 (second high concentration portion 42A) which is exposed from the outer wall 27B.

The semiconductor device 1A includes a source silicide 48 which is formed in a surface layer portion of the source region 17. The source silicide 48 is a film-like region in which silicon positioned at the surface layer portion of the source region 17 and a surface layer portion of the contact region 18 is silicided by a metal. The source silicide 48 contains the n-type impurity (pentavalent element) of the source region 17 and the p-type impurity (trivalent element) of the contact region 18. The metal used in the silicide may be titanium, nickel, chromium, cobalt, tungsten, molybdenum and others (the same shall be applied hereinafter).

The semiconductor device 1A includes a plurality of drain silicides 49 which are each formed in a surface layer portion of the plurality of drain regions 19. Each of the drain silicides 49 is a film-like region in which silicon positioned at the surface layer portion of each of the drain regions 19 is silicided by a metal. Each of the drain silicides 49 includes an n-type impurity (pentavalent element) of each of the drain regions 19.

The semiconductor device 1A includes a gate silicide 50 which is formed in a portion that is exposed from the removing portion 46 in the main surface of the poly-gate 27. The gate silicide 50 may be referred to as a “gate polycide.” Specifically, the gate silicide 50 includes a first gate silicide 50A and a second gate silicide 50B.

The first gate silicide 50A is formed in the first polarity portion 41 (first high concentration portion 41A) which is exposed from the first removing portion 46A in the main surface of the poly-gate 27. The first gate silicide 50A is a film-like region in which polysilicon at the surface layer portion of the first polarity portion 41 is polycided (silicided) by a metal. The first gate silicide 50A contains an n-type impurity (pentavalent element) of the first polarity portion 41. A main surface of the first gate silicide 50A may be positioned on the chip 2 side (gate insulating film 26 side) in relation to a main surface of the cap insulating film 45.

The second gate silicide 50B is formed in the second polarity portion 42 (second high concentration portion 42A) which is exposed from the second removing portion 46B in the main surface of the poly-gate 27. The second gate silicide 50B is a film-like region in which polysilicon at a surface layer portion of the second polarity portion 42 is polycided (silicided) by a metal.

The second gate silicide 50B contains a p-type impurity (trivalent element) of the second polarity portion 42. A main surface of the second gate silicide 50B may have a portion which is positioned on the chip 2 side (gate insulating film 26 side) in relation to the main surface of the cap insulating film 45. The main surface of the second gate silicide 50B may have a portion which protrudes on the field insulating film 22 further above than the main surface of the cap insulating film 45 (on the side opposite to the chip 2).

The semiconductor device 1A includes at least one source contact electrode 51. The source contact electrode 51 is electrically connected to the plurality of source regions 17 and the plurality of contact regions 18 on the first main surface 3 via the source silicide 48. The source contact electrode 51 imparts a source potential Vs to the source region 17 and the contact region 18.

The semiconductor device 1A includes a plurality of drain contact electrodes 52. The plurality of drain contact electrodes 52 are electrically connected to the plurality of drain regions 19 on the first main surface 3 via the drain silicide 49. The drain contact electrode 52 imparts a drain potential Vd to the drain region 19.

The semiconductor device 1A includes a plurality of gate contact electrodes 53. The plurality of gate contact electrodes 53 are arranged on the poly-gate 27 and electrically connected to the poly-gate 27 via the gate silicide 50. Specifically, the plurality of gate contact electrodes 53 include at least one first gate contact electrode 53A (in this embodiment, a plurality of them) and at least one second gate contact electrode 53B (in this embodiment, a plurality of them).

The first gate contact electrode 53A is electrically connected to the first polarity portion 41 via the first gate silicide 50A. The first gate contact electrode 53A imparts a first potential V1 (gate potential Vg) to the first polarity portion 41. The plurality of first gate contact electrodes 53A may be each connected to a portion which is positioned at both end portions of the first polarity portion 41 in the second direction Y. The plurality of first gate contact electrodes 53A are preferably connected to the first high concentration portion 41A.

The second gate contact electrode 53B is electrically connected to the second polarity portion 42 via the second gate silicide 50B. The second gate contact electrode 53B imparts the second potential V2 different from the first potential V1 to the second polarity portion 42. As described previously, the floating potential, the reference potential or the ground potential is given as an example of the second potential V2. The plurality of second gate contact electrodes 53B may be each connected to a portion of the second polarity portion 42 which is positioned at both end portions in the second direction Y. The plurality of second gate contact electrodes 53B are preferably connected to the second high concentration portion 42A.

As described above, the transistor cell 10 includes the channel region 20, the drift region 21 and the planar gate structure 25. The transistor cell 10 is constituted so that a drain/source current will flow during an on operation. During the on operation of the transistor cell 10, the source potential Vs is applied to the source region 17, the drain potential Vd is applied to the drain region 19, and the gate potential Vg is applied to the poly-gate 27.

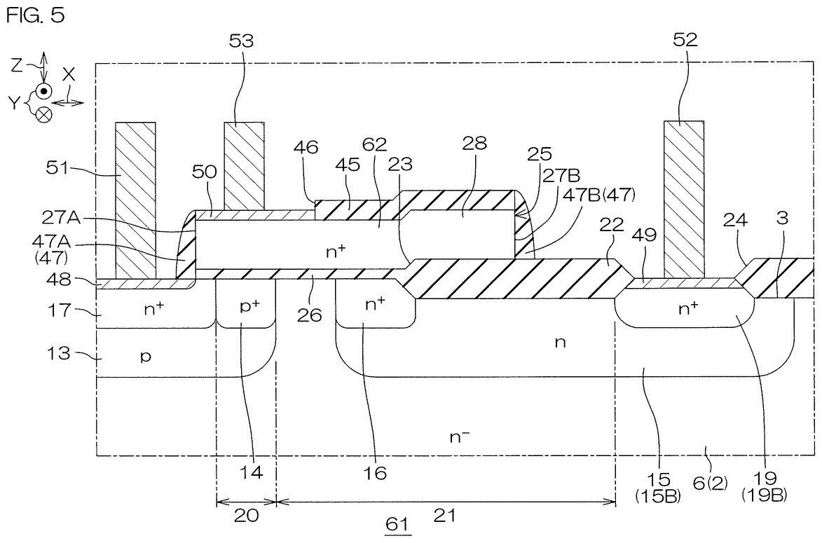

FIG. 5 corresponds to FIG. 4 and is a main portion enlarged view of a semiconductor device 61 according to the first reference embodiment. With reference to FIG. 5, the semiconductor device 61 includes a single conductivity type (in this embodiment, an n-type) poly-gate 62 in place of the poly-gate 27. The semiconductor device 61 may include a p-type poly-gate 62 in place of the n-type poly-gate 62. The semiconductor device 61 does not include a pn-junction diode 29 inside the poly-gate 62.

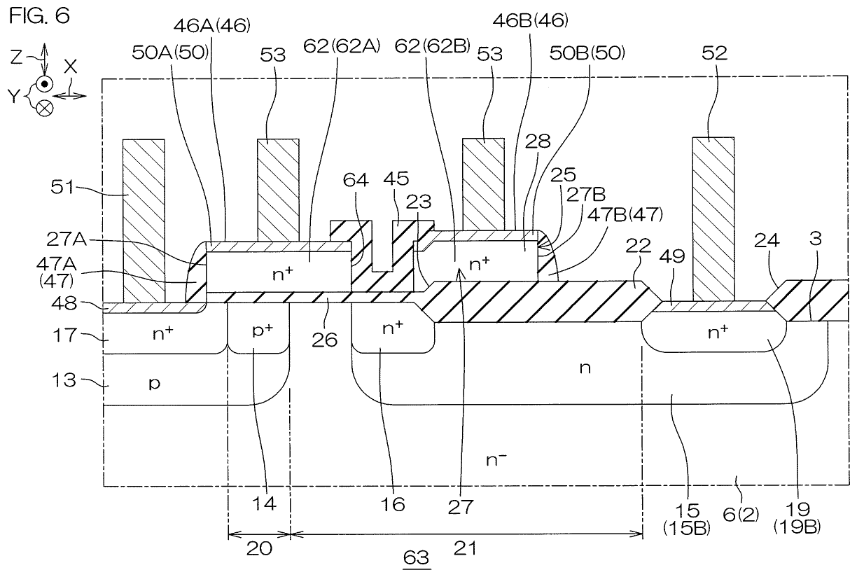

FIG. 6 corresponds to FIG. 4 and is a main portion enlarged view which shows a semiconductor device 63 according to the second reference embodiment. With reference to FIG. 6, as with the semiconductor device 61, the semiconductor device 63 includes a single conductivity type (in this embodiment, an n-type) poly-gate 62 and does not include a pn-junction diode 29 inside the poly-gate 62.

The semiconductor device 63 may include a p-type poly-gate 62 in place of the n-type poly-gate 62. The semiconductor device 63 includes a gate removing portion 64 which separates the poly-gate 62 into a plurality of portions. The poly-gate 62 is separated by the gate removing portion 64 into a first poly-gate 62A on the channel region 20 side and a second poly-gate 62B on the drift region 21 side.

In this embodiment, the first poly-gate 62A is arranged only on a gate insulating film 26 and faces the channel region 20 and the drift region 21 across the gate insulating film 26. In this embodiment, the second poly-gate 62B is led out on a field insulating film 22 from on the gate insulating film 26 and faces the drift region 21 across the gate insulating film 26 and the field insulating film 22. A cap insulating film 45 is interposed between the first poly-gate 62A and the second poly-gate 62B, thereby electrically insulating the first poly-gate 62A and the second poly-gate 62B.

In this embodiment, a gate silicide 50 covers each of a main surface of the first poly-gate 62A and a main surface of the second poly-gate 62B. At least one gate contact electrode 53 is electrically connected to the first poly-gate 62A via the gate silicide 50, and at least one gate contact electrode 53 is electrically connected to the second poly-gate 62B via the gate silicide 50. A gate potential Vg is to be imparted to the first poly-gate 62A, and a floating potential or a source potential Vs is to be imparted to the second poly-gate 62B.

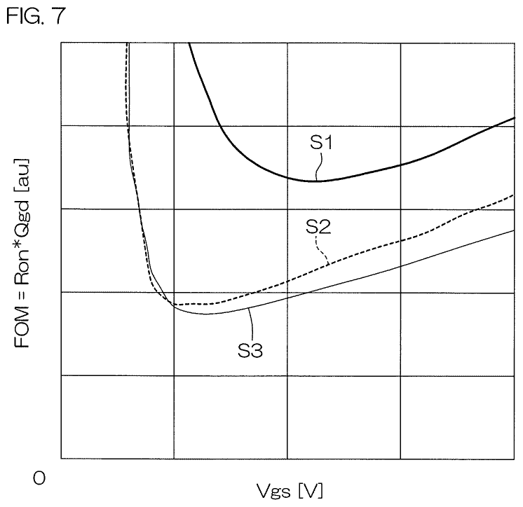

FIG. 7 is a graph which shows a figure of merit (FOM). In FIG. 7, the vertical axis indicates a figure of merit FOM[au] of the transistor cell 10, and the horizontal axis indicates a gate/source voltage Vgs [V] of the transistor cell 10. The figure of merit FOM is defined by a product of an on resistance Ron and an amount of electric charge Qgd between a gate and a drain (FOM=Ron x Qgd). The amount of electric charge Qgd includes an amount of electric charge between the poly-gate 62 and the drift region 21. A smaller value of the figure of merit FOM means a higher performance of the transistor cell 10.

FIG. 7 shows first characteristics S1, second characteristics S2 and third characteristics OM. The first characteristics S1 show a figure of merit FOM of the semiconductor device 61 according to the first reference embodiment. The second characteristics S2 show a figure of merit FOM of the semiconductor device 63 according to the second reference embodiment. The third characteristics S3 shows a figure of merit FOM of the semiconductor device 1A according to the first embodiment.

With reference to the first to third characteristics S1 to S3, the figure of merit FOM according to the semiconductor device 63 is superior to the figure of merit FOM according to the semiconductor device 61, and the figure of merit FOM according to the semiconductor device LA is superior to the figure of merit FOM according to the semiconductor device 63.

In the semiconductor device 61, the amount of electric charge Qgd becomes larger due to the single conductivity type poly-gate 62 which has a relatively large volume. On the other hand, in the semiconductor device 63, the poly-gate 62 is physically separated by the gate removing portion 64 into the first poly-gate 62A on the channel region 20 side and the second poly-gate 62B on the drift region 21 side.

In the poly-gate 62, the first poly-gate 62A which has a relatively small volume functions as a gate electrode for controlling the channel region 20. Thus, the on resistance Ron is elevated, which runs counter to a small amount of electric charge Qgd. Further, the poly-gate 62 has the gate removing portion 64 which is electrically insulated from a gate voltage and, therefore, there develops a region in which the gate voltage is insufficiently applied in the drift region 21. As a result, there develops a region in which the on resistance Ron is elevated in the drift region 21.

In contrast thereto, in the semiconductor device LA, the poly-gate 27 is electrically separated by the pn-junction portion 30 (pn-junction diode 29) into a portion which is positioned on the channel region 20 and a portion which is positioned on the drift region 21. Specifically, the poly-gate 27 includes the first polarity portion 41 which faces the channel region 20 across the gate insulating film 26 and the second polarity portion 42 which faces the drift region 21 across the gate insulating film 26.

According to this structure, the pn-junction portion 30 restricts a carrier which moves from a portion of the poly-gate 27 that is positioned on the channel region to a portion of the poly-gate 27 that is positioned on the drift region 21. Thereby, a portion of the poly-gate 27 which functions as a gate electrode (that is, the first polarity portion 41) is restricted by the pn-junction portion 30. It is, thus, possible to electrically decrease the apparent volume of the poly-gate 27.

Thereby, the amount of electric charge Qgd can be reduced. Further, the poly-gate 27 which is different from the poly-gate 62 according to the semiconductor device 63 is free of a portion which is physically isolated (gate removing portion 64) and, therefore, able to appropriately apply a gate voltage to the drift region 21. Thereby, it is possible to suppress elevation of the on resistance Ron in the drift region 21. Then, the semiconductor device 1A is able to improve the figure of merit FOM, as compared with the semiconductor device 61 and the semiconductor device 63.

As described so far, the semiconductor device 1A according to a first aspect of the first embodiment includes the chip 2, the p-type (first conductivity type) channel region 20, the n-type (second conductivity type) drift region 21, the gate insulating film 26 and the poly-gate 27 (polysilicon gate). The chip 2 has the first main surface 3 (main surface). The channel region 20 is formed in the surface layer portion of the first main surface 3. The drift region 21 is formed so as to be adjacent to the channel region 20 at the surface layer portion of the first main surface 3. The gate insulating film 26 covers the channel region 20 and the drift region 21 on the first main surface 3. The poly-gate 27 is arranged on the gate insulating film 26.

The poly-gate 27 includes the n-type first polarity portion 41 (first portion) and the p-type second polarity portion 42 (second portion). The first polarity portion 41 faces the channel region 20 across the gate insulating film 26. The second polarity portion 42 faces the drift region 21 across the gate insulating film 26 and forms the pn-junction portion 30 with the first polarity portion 41. According to this structure, it is possible to provide the semiconductor device 1A capable of improving the electrical characteristics.

The semiconductor device 1A according to a second aspect of the first embodiment includes the chip 2, the p-type (first conductivity type) channel region 20, the n-type (second conductivity type) drift region 21, the gate insulating film 26, the poly-gate 27 (polysilicon gate) and the pn-junction diode 29. The chip 2 has the first main surface 3 (main surface). The channel region 20 is formed in the surface layer portion of the first main surface 3. The drift region 21 is formed so as to be adjacent to the channel region 20 at the surface layer portion of the first main surface 3. The gate insulating film 26 covers the channel region 20 and the drift region 21 on the first main surface 3.

The poly-gate 27 covers the gate insulating film 26 so as to face the channel region 20 and the drift region 21 across the gate insulating film 26. The pn-junction diode 29 is formed inside the poly-gate 27. The pn-junction diode 29 is constituted so as to restrict a carrier that moves from a portion of the poly-gate 27 which is positioned on the channel region 20 to a portion of the poly-gate 27 which is positioned on the drift region 21. According to this structure, it is possible to provide the semiconductor device 1A capable of improving the electrical characteristics.

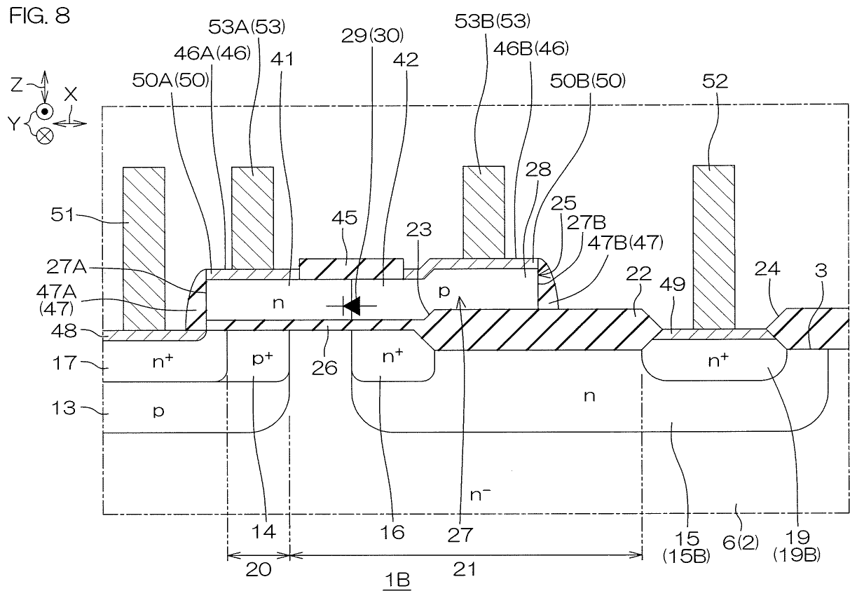

FIG. 8 corresponds to FIG. 4 and is a main portion enlarged view which shows a semiconductor device 1B according to the second embodiment. The semiconductor device 1B is a device which provides the same effects as the semiconductor device 1A. The aforementioned semiconductor device 1A includes the first polarity portion 41 which has the first high concentration portion 41A and the first low concentration portion 41B as well as the second polarity portion 42 which has the second high concentration portion 42A and the second low concentration portion 42B.

In contrast thereto, the semiconductor device 1B includes a first polarity portion 41 which has a uniform n-type impurity concentration and a second polarity portion 42 which has a uniform p-type impurity concentration. The n-type impurity concentration of the first polarity portion 41 may be adjusted to the n-type impurity concentration of the first high concentration portion 41A or the n-type impurity concentration of the first low concentration portion 41B. The p-type impurity concentration of the second polarity portion 42 may be adjusted to the p-type impurity concentration of the second high concentration portion 42A or the p-type impurity concentration of the second low concentration portion 42B.

As a matter of course, while the first polarity portion 41 has the first high concentration portion 41A and the first low concentration portion 41B, the second polarity portion 42 may have a uniform p-type impurity concentration. Further, while the first polarity portion 41 has a uniform n-type impurity concentration, the second polarity portion 42 may have the second high concentration portion 42A and the second low concentration portion 42B.

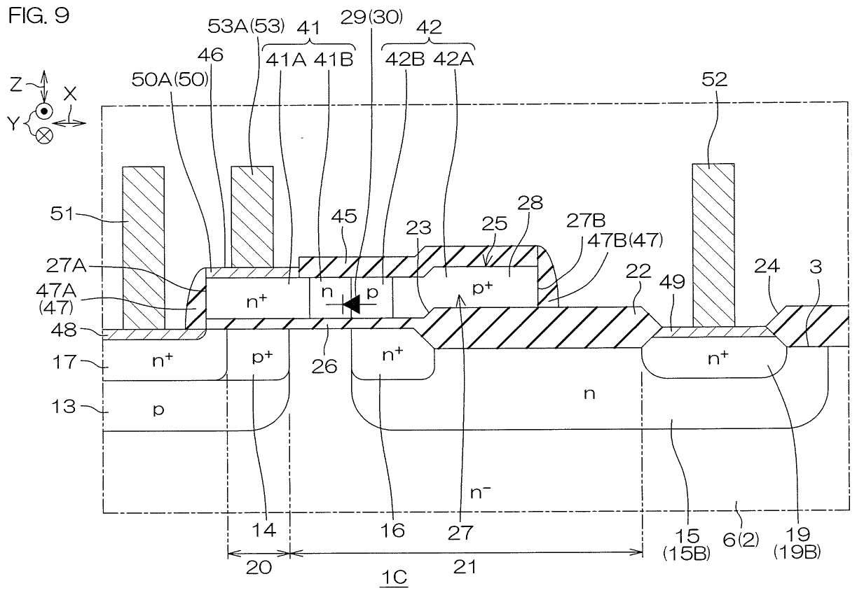

FIG. 9 corresponds to FIG. 4 and is a main portion enlarged view which shows a semiconductor device 1C according to the third embodiment. The semiconductor device 1C is a device which provides the same effects as the semiconductor device 1A and applied to the first or the second embodiment. The semiconductor device 1C is one embodiment where a second polarity portion 42 which is formed in an electrically floating state is adopted.

In this case, since a portion which is electrically connected to the second polarity portion 42 is not needed, a cap insulating film 45 may cover an entire area of the second polarity portion 42. Further, a second gate silicide 50B or a second gate contact electrode 53B may not be formed.

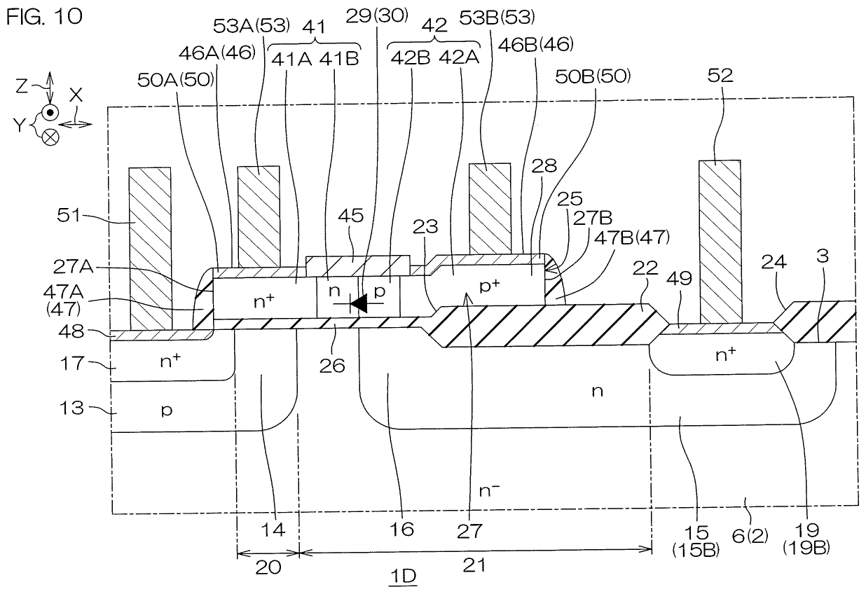

FIG. 10 corresponds to FIG. 4 and is a main portion enlarged view which shows a semiconductor device 1D according to the fourth embodiment. The semiconductor device 1D is a device which provides the same effects as the semiconductor device 1A and applied to any one of the first to third embodiments. The semiconductor device 1A includes the high concentration body region 14 and the high concentration well region 16. In contrast thereto, the semiconductor device 1D does not include one of a high concentration body region 14 and a high concentration well region 16 or includes neither of them (in this embodiment, neither of them).

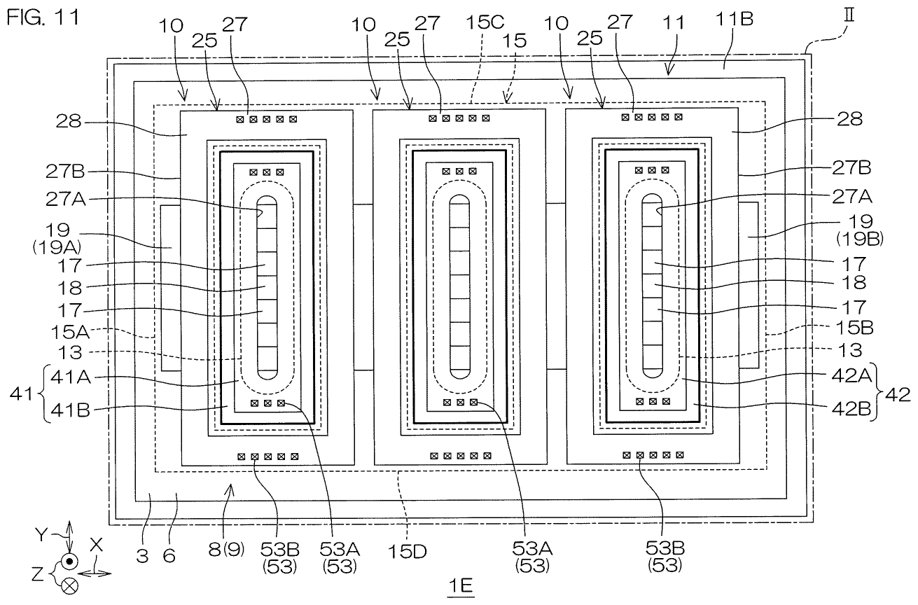

FIG. 11 corresponds to FIG. 2 and is a main portion enlarged view which shows a semiconductor device 1E according to the fifth embodiment. The semiconductor device 1E is a device which provides the same effects as the semiconductor device 1A and applied to any one of the first to fourth embodiments. In each of the aforementioned embodiments, there is shown an example in which one transistor cell 10 is formed in the MIS region 9. However, the plurality (2 or more) of transistor cells 10 may be arrayed in the MIS region 9. In this case, a separation region 11 may be formed in a quadrilateral annular shape (a rectangular annular shape) extending in a first direction X, and the plurality of transistor cells 10 may be arrayed in a single row along the first direction X.

With regard to the two transistor cells 10 which are adjacent to each other, a well region 15 of one of the transistor cells 10 may be integrally formed with a well region 15 of the other of the transistor cells 10. That is, the two transistor cells 10 which are adjacent to each other may have a common well region 15 which is positioned between two body regions 13 that are adjacent to each other (a region in which a first well portion 15A and a second well portion 15B are integrally formed).

In this case, with regard to the two transistor cells 10 which are adjacent to each other, a drain region 19 of one of the transistor cells 10 may be integrally formed with a drain region 19 of the other of the transistor cells 10. That is, the two transistor cells 10 which are adjacent to each other may have a common drain region 19 that is positioned between the two body regions 13 which are adjacent to each other (a region in which a first drain region 19A and a second drain region 19B are integrally formed).

Each of the aforementioned embodiments can be implemented in still other embodiments. In each of the aforementioned embodiments, the separation region 11 is shown as an example of the region separation structure. However, the region separation structure may have a trench insulating structure in place of the separation region 11. The trench insulating structure has a structure in which an insulator is embedded into a trench formed in the first main surface 3. The trench separation structure may be referred to as an STI (Shallow Trench Isolation) structure or a DTI (Deep Trench Isolation) structure.

In each of the aforementioned embodiments, there is shown an example in which the well region 15 includes the first to fourth well portions 15A to 15D. However, there may be adopted a well region 15 which does not include third to fourth well portions 15C to 15D but includes only first to second well portions 15A to 15B. Further, in each of the aforementioned embodiments, there may be adopted a mode in which the well region 15 and the high concentration well region 16 are removed.

In each of the aforementioned embodiments, there is shown an example in which the plurality of source regions 17 are formed at an interval in the second direction Y. However, the plurality (for example, two) of source regions 17 may be formed at an interval in the first direction X in a cross-sectional view. In this case, the contact region 18 may be interposed between the two source regions 17 which are adjacent to each other.

In each of the aforementioned embodiments, the n-type first region 6 is shown. However, the p-type first region 6 may be adopted. In this case, the channel region 20 is formed in a region between the well region 15 and the source region 17 at the surface layer portion of the first main surface 3. In this case, there may be adopted a mode in which the body region 13 and the high concentration body region 14 are removed. As a matter of course, in each of the aforementioned embodiments, the n-type second region 7 may be adopted in place of the p-type second region 7.

In each of the aforementioned embodiments, there has been described an example in which the first conductivity type is a p-type and the second conductivity type is an n-type. However, the first conductivity type may be an n-type and the second conductivity type may be a p-type. A specific constitution of this case can be obtained by replacing the n-type region with the p-type region and also replacing the p-type region with the n-type region in the aforementioned description and the attached drawings.

In each of the aforementioned embodiments, the first direction X and the second direction Y have been regulated by a direction in which the first to fourth side surfaces 5A to 5D of the chip 2 extend. However, the first direction X and the second direction Y may be an arbitrary direction as long as they keep a relationship in which they intersect each other (specifically, orthogonal to each other).

Examples of features extracted from the present description and drawings are shown below. Hereinafter, the semiconductor device capable of improving the electrical characteristics is provided. Hereinafter, although alphanumeric characters within parentheses express corresponding constituents and others in the aforementioned embodiments, these are not meant to limit the scopes of the respective items (Clauses) to the embodiments.

[A1] A semiconductor device (1A to 1E) comprising: a chip (2) which has a main surface (3); a first conductivity type (p-type) channel region (20) which is formed in a surface layer portion of the main surface (3); a second conductivity type (n-type) drift region (21) which is formed in the surface layer portion of the main surface (3) so as to be adjacent to the channel region (20); a gate insulating film (26) which covers the channel region (20) and the drift region (21) on the main surface (3); and a polysilicon gate (27) which has a second conductivity type (n-type) first portion (41) that faces the channel region (20) across the gate insulating film (26) and a first conductivity type (p-type) second portion (42) that faces the drift region (21) across the gate insulating film (26) and forms a pn-junction portion (30) with the first portion (41).

[A2] The semiconductor device (1A to 1E) according to A1, wherein a gate potential (Vg, V1) is to be imparted to the first portion (41), and a potential (V2) other than the gate potential (Vg, V1) is to be imparted to the second portion (42).

[A3] The semiconductor device (1A to 1E) according to A1 or A2, wherein a potential difference (V12) between the first portion (41) and the second portion (42) is less than a threshold voltage (Vdth) of the pn-junction portion (30).

[A4] The semiconductor device (1A to 1E) according to any one of A1 to A3, wherein a floating potential, a reference potential which serves as a reference of circuit operation, or a ground potential is to be imparted to the second portion (42).

[A5] The semiconductor device (1A to 1E) according to any one of A1 to A4, wherein the second portion (42) is formed in an electrically floating state.

[A6] The semiconductor device (1A to 1E) according to any one of A1 to A5, wherein the first portion (41) faces the channel region (20) and the drift region (21) across the gate insulating film (26).

[A7] The semiconductor device (1A to 1E) according to any one of A1 to A6, wherein the pn-junction portion (30) faces the drift region (21) across the gate insulating film (26).

[A8] The semiconductor device (1A to 1E) according to any one of A1 to A7, wherein the first portion (41) has a first high concentration portion (41A) and a first low concentration portion (41B) lower in concentration than the first high concentration portion (41A), and the second portion (42) forms the pn-junction portion (30) with the first low concentration portion (41B) of the first portion (41).

[A9] The semiconductor device (1A to 1E) according to A8, wherein the second portion (42) has a second high concentration portion (42A) and a second low concentration portion (42B) which is lower in concentration than the second high concentration portion (42A) and forms the pn-junction portion (30) with the first low concentration portion (41B).

[A10] The semiconductor device (1A to 1E) according to any one of A1 to A9, further comprising: an insulating film (45) which covers the pn-junction portion (30) on the polysilicon gate (27).

[A11] The semiconductor device (1A to 1E) according to A10, wherein the insulating film (45) includes a removing portion (46) which exposes a portion other than the pn-junction portion (30) on the polysilicon gate (27).

[A12] The semiconductor device (1A to 1E) according to A11, further comprising: a gate silicide (50) which covers a portion exposed from the removing portion (46) in the polysilicon gate (27).

[A13] The semiconductor device (1A to 1E) according to A12, wherein the removing portion (46) includes a first removing portion (46A) which exposes the first portion (41) and a second removing portion (46B) which exposes the second portion (42), and the gate silicide (50) includes a first gate silicide (50A) which covers the first portion (41) and a second gate silicide (50B) which covers the second portion (42).

[A14] The semiconductor device (1A to 1E) according to any one of A1 to A13, further comprising: a field insulating film (22) which covers the drift region (21) on the main surface (3); wherein the gate insulating film (26) has a thickness less than a thickness of the field insulating film (22) and continues to the field insulating film (22).

[A15] The semiconductor device (1A to 1E) according to A14, wherein the polysilicon gate (27) is led out on the field insulating film (22) from on the gate insulating film (26) and faces the drift region (21) across the field insulating film (22).

[A16] The semiconductor device (1A to 1E) according to A15, wherein the first portion (41) is formed only on the gate insulating film (26), and the second portion (42) is formed on the gate insulating film (26) and on the field insulating film (22).

[A17] The semiconductor device (1A to 1E) according to any one of A1 to A16, further comprising: a second conductivity type (n-type) source region (17) which is formed in the surface layer portion of the main surface (3); and a second conductivity type (n-type) drain region (19) which is formed in the surface layer portion of the main surface (3) at an interval from the source region (17); wherein the channel region (20) is formed in the surface layer portion of the main surface (3) in a region on the source region (17) side between the source region (17) and the drain region (19), and the drift region (21) is formed in the surface layer portion of the main surface (3) in a region between the drain region (19) and the channel region (20).

[A18] The semiconductor device (1A to 1E) according to A17, further comprising: a first conductivity type (p-type) body region (13) which is formed in the surface layer portion of the main surface (3); and a second conductivity type (n-type) well region (15) which is formed in the surface layer portion of the main surface (3) at an interval from the body region (13); wherein the source region (17) is formed in a surface layer portion of the body region (13), the drain region (19) is formed in a surface layer portion of the well region (15), and the first portion (41) faces the body region (13) and the source region (17) across the gate insulating film (26).

[A19] The semiconductor device (1A to 1E) according to any one of A1 to A18, further comprising: a region separation structure (11) which is formed in the main surface (3) so as to demarcate a part of the main surface (3) as a device region (8, 9); wherein the channel region (20) and the drift region (21) are formed in the device region (8, 9).

[B1] A semiconductor device (1A to 1E) comprising: a chip (2) which has a main surface (3); a first conductivity type (p-type) channel region (20) which is formed in a surface layer portion of the main surface (3); a second conductivity type (n-type) drift region (21) which is formed in the surface layer portion of the main surface (3) so as to be adjacent to the channel region (20); a gate insulating film (26) which covers the channel region (20) and the drift region (21) on the main surface (3); a polysilicon gate (27) which covers the gate insulating film (26) so as to face the channel region (20) and the drift region (21) across the gate insulating film (26); and a pn-junction diode (29) which is formed inside the polysilicon gate (27).

[B2] The semiconductor device (1A to 1E) according to B1, wherein the pn-junction diode (29) is formed so as to restrict a carrier that moves from a portion of the polysilicon gate (27) which is positioned on the channel region (20) to a portion of the polysilicon gate (27) which is positioned on the drift region (21).

[C1] A semiconductor device (1A to 1E) comprising: a chip (2) which has a main surface (3); a first conductivity type (p-type) channel region (20) which is formed in a surface layer portion of the main surface (3); a second conductivity type (n-type) drift region (21) which is formed in the surface layer portion of the main surface (3) so as to be adjacent to the channel region (20); a gate insulating film (26) which covers the channel region (20) and the drift region (21) on the main surface (3); a polysilicon gate (27) which covers the gate insulating film (26) so as to face the channel region (20) and the drift region (21) across the gate insulating film (26) and has a first wall (27A) on the channel region (20) side and a second wall (27B) on the drift region side; and a pn-junction diode (29) which is formed inside the polysilicon gate (27) so as to restrict a carrier which moves from the first wall (27A) side to the second wall (27B) side inside the polysilicon gate (27).

[C2] The semiconductor device (1A to 1E) according to C1, wherein the pn-junction diode is constituted so that a potential difference (V12) between the first wall (27A) and the second wall (27B) will be less than a threshold voltage (Vdth).

Although the embodiments have been described in detail, these embodiments are merely specific examples used to clarify the technical contents, and the present invention should not be interpreted by being limited to these specific examples, and the scope of the present invention is limited by the appended claims.

What is claimed is:

1. A semiconductor device comprising:
a chip which has a main surface;
a first conductivity type channel region which is formed in a surface layer portion of the main surface;
a second conductivity type drift region which is formed in the surface layer portion of the main surface so as to be adjacent to the channel region;
a gate insulating film which covers the channel region and the drift region on the main surface; and
a polysilicon gate which includes a second conductivity type first portion which faces the channel region across the gate insulating film and a first conductivity type second portion which faces the drift region across the gate insulating film and forms a pn-junction portion with the first portion.

2. The semiconductor device according to claim 1,
wherein a gate potential is to be imparted to the first portion, and
a potential other than the gate potential is to be imparted to the second portion.

3. The semiconductor device according to claim 1,
wherein a potential difference between the first portion and the second portion is less than a threshold voltage of the pn-junction portion.

4. The semiconductor device according to claim 1,
wherein a floating potential, a reference potential which serves as a reference of circuit operation, or a ground potential is to be imparted to the second portion.

5. The semiconductor device according to claim 1,
wherein the second portion is formed in an electrically floating state.

6. The semiconductor device according to claim 1,
wherein the first portion faces the channel region and the drift region across the gate insulating film.

7. The semiconductor device according to claim 1,
wherein the pn-junction portion faces the drift region across the gate insulating film.

8. The semiconductor device according to claim 1,
wherein the first portion has a first high concentration portion and a first low concentration portion which is lower in concentration than the first high concentration portion, and
the second portion forms the pn-junction portion with the first low concentration portion of the first portion.

9. The semiconductor device according to claim 8,
wherein the second portion has a second high concentration portion and a second low concentration portion which is lower in concentration than the second high concentration portion and forms the pn-junction portion with the first low concentration portion.

10. The semiconductor device according to claim 1, further comprising:
an insulating film which covers the pn-junction portion on the polysilicon gate.

11. The semiconductor device according to claim 10,
wherein the insulating film includes a removing portion which exposes a portion other than the pn-junction portion on the polysilicon gate.

12. The semiconductor device according to claim 11, further comprising:
a gate silicide which covers a portion that is exposed from the removing portion at the polysilicon gate.

13. The semiconductor device according to claim 12,
wherein the removing portion includes a first removing portion which exposes the first portion and a second removing portion which exposes the second portion, and
the gate silicide incudes a first gate silicide which covers the first portion and a second gate silicide which covers the second portion.

14. The semiconductor device according to claim 1, further comprising:
a field insulating film which covers the drift region on the main surface;
wherein the gate insulating film has a thickness which is less than a thickness of the field insulating film and continues to the field insulating film.

15. The semiconductor device according to claim 14,
wherein the polysilicon gate is led out on the field insulating film from on the gate insulating film and faces the drift region across the field insulating film.

16. The semiconductor device according to claim 15,
wherein the first portion is formed only on the gate insulating film, and
the second portion is formed on the gate insulating film and on the field insulating film.

17. The semiconductor device according to claim 1, further comprising:
a second conductivity type source region which is formed in the surface layer portion of the main surface; and
a second conductivity type drain region which is formed in the surface layer portion of the main surface at an interval from the source region;
wherein the channel region is formed in the surface layer portion of the main surface in a region on the source region side between the source region and the drain region, and
the drift region is formed in the surface layer portion of the main surface in a region between the drain region and the channel region.

18. The semiconductor device according to claim 17 further comprising:
a first conductivity type body region which is formed in the surface layer portion of the main surface; and
a second conductivity type well region which is formed in the surface layer portion of the main surface at an interval from the body region;
wherein the source region is formed in a surface layer portion of the body region, the drain region is formed in a surface layer portion of the well region, and
the first portion faces the body region and the source region across the gate insulating film.

19. The semiconductor device according to claim 1, further comprising:
a region separation structure which is formed in the main surface so as to demarcate a part of the main surface as a device region;
wherein the channel region and the drift region are formed in the device region.

20. A semiconductor device comprising:
a chip which has a main surface;
a first conductivity type channel region which is formed in a surface layer portion of the main surface;
a second conductivity type drift region which is formed in the surface layer portion of the main surface so as to be adjacent to the channel region;
a gate insulating film which covers the channel region and the drift region on the main surface;
a polysilicon gate which covers the gate insulating film so as to face the channel region and the drift region across the gate insulating film; and
a pn-junction diode which is formed inside the polysilicon gate so as restrict a carrier that moves from a portion of the polysilicon gate which is positioned on the channel region to a portion of the polysilicon gate which is positioned on the drift region.
